(19) United States
(12) Patent Application Publication
(10) Pub. No.: US 2018/0229329 A1
(43) Pub. Date: Aug. 16, 2018

(54) BONDING APPARATUS

(71) Applicant: Samsung Electronics Co., Ltd., Suwon-si (KR)

(72) Inventors: MYUNG IL KIM, Cheonan-si (KR); KYOUNG BOK CHO, Cheonan-si (KR); YOUNG DAE HA, Asan-si (KR)

(21) Appl. No.: 15/859,445

(22) Filed: Dec. 30, 2017

(30) Foreign Application Priority Data
Feb. 13, 2017 (KR) 10-2017-0019236

(51) Int. Cl. B23K 20/00; H01L 23/00

(52) U.S. Cl. CPC B23K 20/004; H01L 24/78; B23K 2201/40; H01L 2224/78621; H01L 2224/7865

(57) ABSTRACT

A bonding apparatus can include a console which controls bonding of at least one wire, a first bonding unit disposed on the console to bond a first wire to a first substrate, a second bonding unit disposed on the first bonding unit to bond a second wire to a second substrate different from the first substrate, and a vibration damping unit connected to the second bonding unit preventing vibrations generated in the second bonding unit from transmitting to the first bonding unit.

This application claims priority under 35 U.S.C. § 119 to Korean Patent Application No. 10-2017-0019236 filed on Feb. 13 2017 in the Korean Intellectual Property Office, the disclosure of which is incorporated herein by reference in its entirety.

### BACKGROUND

The present inventive concept relates to a bonding apparatus.

DESCRIPTION OF THE RELATED ART

A bonding apparatus is an apparatus which bonds semiconductor chips to printed circuit boards. Generally, a general discrete chip resistor or a general discrete chip capacitor is mounted on the surface of the printed circuit board. However, an embedded package in which active components such as a memory or an application processor are embedded in a printed circuit board has been recently developed.

Wiring between components is shortened by mounting the components inside the embedded package, increasing reliability and stabilizing electrical characteristics. In addition, since the module can be configured with a substrate area smaller than an external printed circuit board, the module can be applied to various types of portable electronic devices. For example, the module may be used for various applications such as greatly reducing the size of the semiconductor package, and preventing the damage to the semiconductor chip.

### SUMMARY

According to an exemplary embodiment of the present disclosure, there is provided a bonding apparatus, a console which controls bonding of at least one wire, a first bonding unit disposed on the console to bond a first wire to a first substrate, a second bonding unit disposed on the first bonding unit to bond a second wire to a second substrate different from the first substrate, and a vibration damping unit connected to the second bonding unit to prevent vibrations generated in the second bonding unit from transmitting to the first bonding unit. Thus, allowing a plurality of bonding units to be driven independently of each other to bond a plurality of wires to a plurality of different substrates.

According to an exemplary embodiment of the present disclosure, there is provided a bonding apparatus, a first stage on which a first substrate is disposed, a second stage, which is disposed on the first stage, and on which a second substrate different from the first substrate is disposed, a first loader which loads the first substrate onto the first stage in a first direction, a second loader which loads the second substrate onto the second stage in the first direction, a first unloader which unloads the first substrate from the first stage in the first direction, a second unloader which unloads the second substrate from the second stage in the first direction, a first bonding head disposed between the first stage and the second stage to bond a first wire to the first substrate, a second bonding head disposed on the second stage to bond a second wire to the second substrate, and a vibration damping unit which prevents vibrations generated in the second bonding head from transmitting to the first bonding head. Thus, a plurality of stages may be driven independently of each other to bond a plurality of wires to a plurality of different substrates.

According to an exemplary embodiment of the present invention there is provided a bonding apparatus, a console which controls bonding of at least one wire, a first bonding unit disposed on the console to bond a first wire to a first substrate, a second bonding unit disposed on the first bonding unit to bond a second wire to a second substrate different from the first substrate, a first vibration damping unit connected to the second bonding unit to prevent vibrations generated in the second bonding unit from transmitting to the first bonding unit, a third bonding unit disposed on the console and spaced apart from the first bonding unit in a second direction, to bond a third wire to a third substrate different from the first substrate and second substrate, a fourth bonding unit disposed on the third bonding unit to bond a fourth wire to a fourth substrate different from the first and second and third substrates, and a second vibration damping unit connected to the fourth bonding unit to prevent vibrations generating in the fourth bonding unit from transmitting to the third bonding unit. Thus, a plurality of bonding units may be driven independently of each other to bond a plurality of wires to a plurality of different substrates.

The problems to be solved by the present disclosure are not limited to the aforementioned aspects and another problem which is not mentioned will be clearly understood by those skilled in the art from the following description.

### BRIEF DESCRIPTION OF DRAWINGS

These and other exemplary embodiments and features of the present disclosure will become more apparent by describing in detail exemplary embodiments thereof with reference to the attached drawings, in which:

FIG. 1 is a diagram for explaining a bonding apparatus according to an exemplary embodiment of the present inventive concept;

FIG. 2 is a plan view of the bonding apparatus illustrated in FIG. 1 according to an exemplary embodiment of the present inventive concept;

FIG. 3 to FIG. 6 are diagrams for explaining a bonding process of the bonding apparatus according to an exemplary embodiment of the present inventive concept;

FIG. 7 is a diagram for explaining a vibration damping unit of a bonding apparatus according to an exemplary embodiment of the present inventive concept;

FIG. 8 is a diagram for explaining a bonding apparatus according to an exemplary embodiment of the present inventive concept;

FIG. 9 is a diagram for explaining a bonding apparatus according to an exemplary embodiment of the present inventive concept;

FIG. 10 is a plan view of the bonding apparatus illustrated in FIG. 9;

FIG. 11 is a diagram for explaining a bonding apparatus according to an exemplary embodiment of the present inventive concept;

FIG. 12 is a plan view of the bonding apparatus illustrated in FIG. 11;

FIG. 13 is a plan view for explaining a bonding apparatus according to an exemplary embodiment of the present inventive concept; and

FIG. 14 is a plan view of the bonding apparatus illustrated in FIG. 13 from another angle.

It should be noted that these figures are intended to illustrate the general characteristics of methods, structure and/or materials utilized in an exemplary embodiment and to supplement the written description provided below. These drawings are not, however, to scale and may not precisely reflect the precise structural or performance characteristics of any given embodiment, and should not be interpreted as defining or limiting the range of values or properties encompassed by a given exemplary embodiment. For example, the relative thicknesses and positioning of layers, regions and/or structural elements may be reduced or exaggerated for clarity. The use of similar or identical reference numbers in the various drawings is intended to indicate the presence of a similar or identical element or feature.

### DETAILED DESCRIPTION

Unless otherwise specified, all terms (including technical and scientific terms) used in this specification may be used as the meaning that can be commonly understood by those having ordinary skill in the technical field to which the present inventive concept pertains. Also, terms commonly used and defined by a dictionary are not ideally or unduly interpreted unless otherwise clearly defined.

As defined herein a ‘wire’ may comprise bonding wire. Specifically, a wire may comprise at least one of gold, aluminium, silver, or copper. A wire may also comprise an alloy thereof. Furthermore, a wire may be doped with additional elements, for example beryllium. Also, the wire may be coated such as known in the art, for example palladium may be used to coat a silver wire. Further, the shape and size of a wire herein may vary. Any shape known in the art, such as a circular cross section, may be used. Additionally, any size known in the art, such as between 12.5-500 micrometres, may be used.

As defined herein, a ‘substrate’ may comprise bulk silicon. Alternatively, a substrate may comprise a silicon substrate or may contain other materials, for example, at least one of a silicon germanium, indium antimonide, lead tellurium compound, indium arsenide, phosphide indium, gallium arsenide, or gallium antimonide. Further, a substrate may be configured so that an epitaxial layer is disposed on a base substrate. However, a substrate may also comprise a packaging substrate, for example, a printed circuit board (PCB).

As defined herein a ‘semiconductor chip’ may comprise a non-volatile memory chip. Specifically, a semiconductor chip may be a flash memory chip. More specifically, a semiconductor chip may be a NAND flash memory chip or a NOR flash memory chip. However, a semiconductor chip is not limited thereto, and should be reasonably understood as any referring to any chip known in the art. That is, in other embodiments, a semiconductor chip may contain one or more phase-change random-access memory (PRAM), a magneto-resistive random-access memory (MRAM), or a resistive random-access memory (RRAM).

When semiconductor chips are non-volatile memory chips, they may be packaged in a variety of various methods using the appropriate substrates. For example, the semiconductor chips may be packaged by method such as PoP (Package on Package), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), system in package (SIP), multi-chip package (MCP), wafer-level fabricated package (WFP), wafer-level processed stack package (WSP) or the like.

Furthermore, as defined herein, the terms damping and dampening may be used interchangeably.

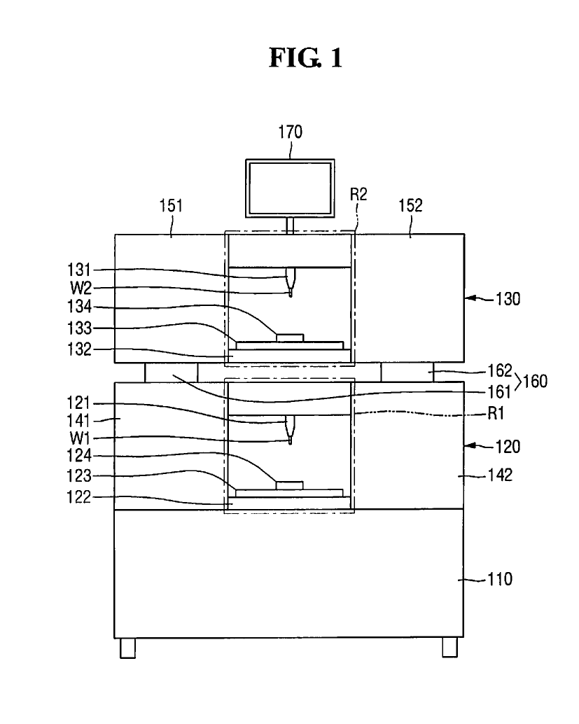

Hereinafter, a bonding apparatus according to an exemplary embodiment of the present inventive concept will be described with reference to FIG. 1 to FIG. 6.

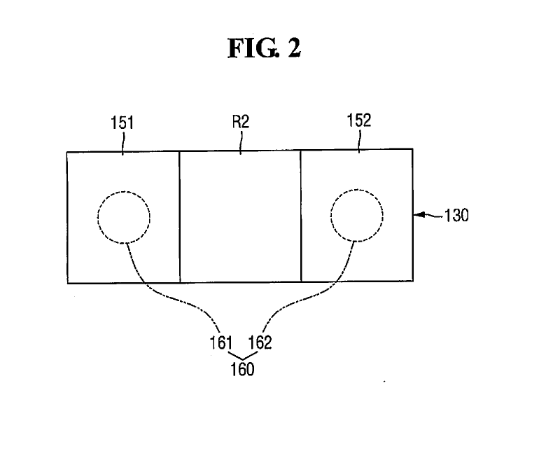

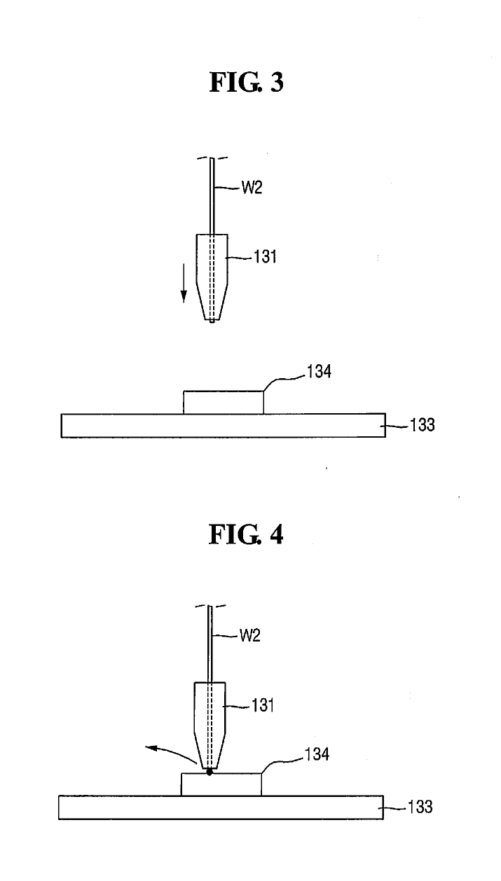

FIG. 1 is a diagram for explaining a bonding apparatus according to an exemplary embodiment of the present inventive concept. FIG. 2 is a plan view of the bonding apparatus illustrated in FIG. 1. FIG. 3 to FIG. 6 are diagrams for explaining a bonding process of a bonding apparatus according to an exemplary embodiment of the present inventive concept. For convenience of explanation, a monitor 170 is not illustrated in FIG. 2.

Referring to FIG. 1 to FIG. 6, a bonding apparatus according to an exemplary embodiment of the present inventive concept includes a console 110, a first bonding unit 120, a second bonding unit 130, a vibration damping unit 160 and a monitor 170.

The console 110 may control bonding of at least one wire. Specifically, the console 110 controls the first bonding unit 120 using a control unit (e.g., a computer) installed inside, thereby bonding a first wire W1 to a first substrate 123, and a first semiconductor chip 124 disposed on the first substrate 123. Further, the console 110 controls the second bonding unit 130 using a control unit (e.g., a computer) installed inside, thereby bonding a second wire W2 to a second substrate 133 and different from the first substrate 123, and a second semiconductor chip 134 disposed on the second substrate 133. Additionally, the first wire W1 and second wire W2 may be identical, or may differ in one or more of size, shape, or composition.

FIG. 3 to FIG. 6 illustrate a configuration in which a wire bonding process is performed on the second substrate 133 and the second semiconductor chip 134 in the second bonding unit 130 with a second wire W2. Although not illustrated, it should be recognized that an equivalent wire bonding process may also be performed on the first substrate 123 and the first semiconductor chip 124 in the first bonding unit 120 with a first wire W1.

Referring to FIG. 3, the second bonding head 131, disposed so that the second wire W2 passes therethrough, is first located on the second semiconductor chip 134. Subsequently, the second bonding head 131 may be lowered to the upper surface of the second semiconductor chip 134.

Referring to FIG. 4, the second bonding head 131, now lowered to the upper surface of the second semiconductor chip 134, may bond the second wire W2 to the second semiconductor chip 134. Subsequently, the second bonding head 131 may be moved onto the second substrate 133 on which the second semiconductor chip 134 is not disposed.

In this case, vibrations may be generated by driving the second bonding head 131. However, since the movement of the second bonding head 131 is stopped when the second wire W2 is bonded to the second semiconductor chip 134 and the second substrate 133, the reliability of the wire bonding performed on the second semiconductor chip 134 and the second substrate 133 is not affected.

However, vibrations generated by the movement of the second bonding head 131 may affect the reliability of the wire bonding which is performed in another bonding unit in vibrational contact with the second bonding unit 130.

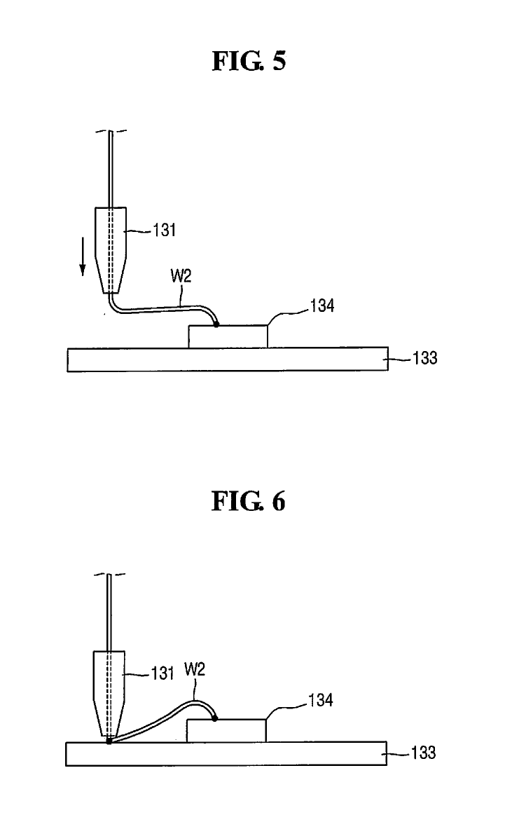

Referring to FIG. 5, the second bonding head 131 is moved over a region of the second substrate 133 where the second semiconductor chip 134 is not disposed, and may be lowered onto the upper surface of the second substrate 133.

Referring to FIG. 6, the second bonding head 131, lowered to the upper surface of the second substrate 133, may bond the second wire W2 to the second substrate 133. Subsequently, the wire bonding process may be completed by cutting the second wire W2 between the second bonding head 131 and the second substrate 133.

In the embodiment discussed above with respect to FIGS. 3-6, the second wire W2 may first be bonded to the second semiconductor chip 134 and then be bonded to the second substrate 133. In another embodiment, however, the second wire W2 may be first bonded to the second substrate 133, and then the second wire W2 may be bonded to the second semiconductor chip 134 (e.g., in a reverse order of steps compared to that shown in FIG. 3-6).

Referring again to FIG. 1 to FIG. 6, the first and second substrates 123 and 133 may be silicon substrates based on a semiconductor wafer. In an exemplary embodiment, the first and second substrates 123 and 133 may each be a packaging substrate (e.g., a printed circuit board (PCB)). In another exemplary embodiment, the first and second substrates 123 and 133 may be, for example, bulk silicon. Alternatively, the first and second substrates 123 and 133 may be silicon substrates or may contain other materials or compounds such as, for example, at least one of silicon germanium, indium antimonide, lead tellurium compound, indium arsenide, phosphide indium, gallium arsenide, or gallium antimonide. Further, the first and second substrates 123 and 133 may be configured so that an epitaxial layer is disposed on a base substrate.

The first and second semiconductor chips 124 and 134 may be manufactured, using silicon-on-insulator (SDI), silicon germanium or the like, but the present inventive concept is not limited thereto.

Further, the first and second semiconductor chips 124 and 134 may be, for example, non-volatile memory chips. Specifically, the first and second semiconductor chips 124 and 134 may be flash memory chips. More specifically, the first and second semiconductor chips 124 and 134 may be a NAND flash memory chip or a NOR flash memory chip.

However, the first and second semiconductor chips 124 and 134 are not limited thereto. That is, in other embodiments, the first and second semiconductor chips 124 and 134 may contain one or more phase-change random-access memory (PRAM), a magneto-resistive random-access memory (MRAM), or a resistive random-access memory (RRAM).

When the first and second semiconductor chips 124 and 134 are non-volatile memory chips, they may be packaged in a variety of various methods. For example, the first and second semiconductor chips 124 and 134 may be packaged by method such as PoP (Package on Package), ball grid arrays (BGAs), chip scale packages (CSPs), plastic leaded chip carrier (PLCC), plastic dual in- line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), system in package (SIP), multi-chip package (MCP), wafer-level fabricated package (WFP), wafer-level processed stack package (WSP) or the like.

Also, in other embodiments, each of the first and second semiconductor chips 124 and 134 may be a packaging substrate (e.g., a printed circuit board (PCB)).

The console 110 may independently control the first bonding unit 120 and/or the second bonding unit 130. For example, the console 110 may drive only one of the first bonding unit 120 and the second bonding unit 130, or console 110 may drive both the first bonding unit 120 and the second bonding unit 130 simultaneously.

The first bonding unit 120 may be disposed on the console 110. The first bonding unit 120 may be controlled by the console 110. The first bonding unit 120 may bond a first wire W1 to the first substrate 123 and the first semiconductor chip 124 loaded to the inside of the first bonding unit 120.

The first bonding unit 120 includes a first stage 122 on which the first substrate 123 is disposed, a first bonding head 121 disposed on the first stage 122, a first loader 141 disposed on one side of the first bonding region R1 of the first bonding unit 120, and a first unloader 142 disposed on the other side of the first bonding region R1 of the first bonding unit 120. Thus, the first loader 141 and first unloader 142 are spaced apart from one another in a first direction, with the first bonding region R1 interposed therebetween.

Although not illustrated in FIG. 1, the first stage 122 may include a heater which transfers heat to the first substrate 123, and a cooler which cools the first substrate 123. Thus, the first stage 122 may include a substance having a relatively high thermal conductivity.

The first loader 141 may load the first substrate 123 and the first semiconductor chip 124 to the first bonding region R1 of the first bonding unit 120 provided with the first bonding head 121. In this case, the first substrate 123 and the first semiconductor chip 124 may be loaded to the top of the first stage 122 installed in the first bonding region R1 of the first bonding unit 120.

The first bonding head 121 may move over the first stage 122 in a horizontal direction or a vertical direction, using a moving unit (not shown) installed in the first bonding region R1 of the first bonding unit 120.

The first bonding head 121 may bond a first wire W1 to each of the first substrate 123 and the first semiconductor chip 124 loaded to the top of the first stage 122.

The first unloader 142 may unload the first substrate 123 and the first semiconductor chip 124, after the wire bonding is completed, from the first bonding region R1 of the first bonding unit 120. In this case, the first substrate 123 and the first semiconductor chip 124 may be unloaded to the first unloader 142 from the top of the first stage 122 installed in the first bonding region R1 of the first bonding unit 120.

The second bonding unit 130 may be disposed on the first bonding unit 120. The second bonding unit 130 may be controlled by the console 110. The second bonding unit 130 may bond a second wire W2 to each of the second substrate 133 and the second semiconductor chip 134 loaded to the inside of the second bonding unit 130.

The second bonding unit 130 includes a second stage 132 on which the second substrate 133 is disposed, a second bonding head 131 disposed on the second stage 132, a second loader 151 disposed on one side of the second bonding region R2 of the second bonding unit 130, and a second unloader 152 disposed on the other side of the second bonding region R2 of the second bonding unit 130. Thus, the second loader 151 and second unloader 152 are spaced apart from one another in the first direction, with the second bonding region R2 interposed therebetween.

Although not illustrated in FIG. 1, the second stage 132 may include a heater which transfers heat to the second substrate 133, and a cooler which cools the second substrate 133. Thus, the second stage 132 may include a substance having a relatively high thermal conductivity.

The second loader 151 may load the second substrate 133 and the second semiconductor chip 134 to the second bonding region R2 of the second bonding unit 130 provided with the second bonding head 131. In this case, the second substrate 133 and the second semiconductor chip 134 may be loaded to the top of the second stage 132 installed in the second bonding region R2 of the second bonding unit 130.

The second bonding head 131 may move over the second stage 132 in the horizontal direction or the vertical direction, using a moving unit (not shown) installed in the second bonding region R2 of the second bonding unit 130.

The second bonding head 131 may bond a second wire W2 to each of the second substrate 133 and the second semiconductor chip 134 loaded to the top of the second stage 132.

The second unloader 152 may unload the second substrate 133 and the second semiconductor chip 134, after the wire bonding is completed, from the second bonding region R2 of the second bonding unit 130. In this case, the second substrate 133 and the second semiconductor chip 134 may be unloaded to the second unloader 152 from the top of the second stage 132 installed in the second bonding region R2 of the second bonding unit 130.

The present specification exemplarily illustrates a configuration in which the two bonding units, that is, the first bonding unit 120 and the second bonding unit 130 are vertically stacked on the console 110, but the present inventive concept is not limited thereto. That is, in other embodiments, three or more bonding units may be vertically stacked on the console 110.

FIG. 1 illustrates a configuration in which the first loader 141 and the first unloader 142 are disposed on both sides of the first bonding region R1, and the second loader 151 and the second unloader 152 are disposed on both sides of the second bonding region R2. However, the arrangement positions of the first loader 141 and the first unloader 142, and the arrangement positions of the second loader 151 and the second unloader 152 are not limited.

That is, in other embodiments, both the first loader 141 and the first unloader 142 may be disposed on the same side of the first bonding region R1. Also, both the second loader 151 and the second unloader 152 may be disposed on the same side of the second bonding region R2.

The vibration damping unit 160 may be disposed between the first bonding unit 120 and the second bonding unit 130. The vibration damping unit 160 may include a plurality of individual damping units (e.g., a first vibration damping unit 161 and a second vibration damping unit 162). More specifically, the first vibration damping unit 161 may be disposed between the first loader 141 and the second loader 151 to connect the upper surface of the first loader 141 and the lower surface of the second loader 151. Further, the second vibration damping unit 162 may be disposed between the first unloader 142 and the second unloader 152 to connect the upper surface of the first unloader 142 and the lower surface of the second unloader 152.

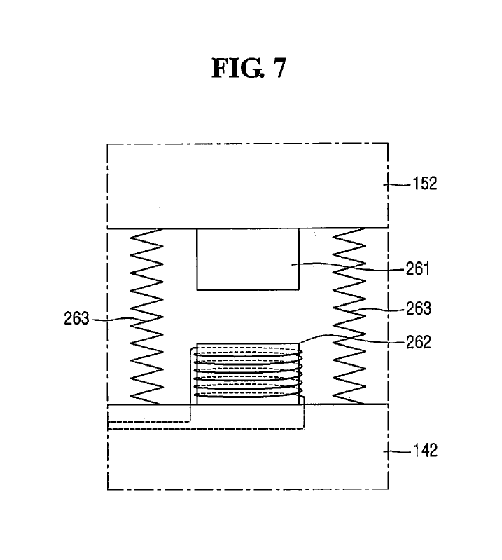

The vibration damping unit 160 may perform a buffering function. For example, each of the first vibration damping unit 161 and the second vibration damping unit 162 may include a spring, a rubber pad, or the like. However, the present inventive concept is not limited thereto. That is, in other embodiments, the vibration damping unit 160 may include other structures or materials capable of performing the buffering function. The vibration damping unit 160 may further comprise a similar unit as presented in FIG. 7 below.

The vibration damping unit 160 may prevent vibrations generated in the second bonding unit 130 from transmitted to the first bonding unit 120. Further, the vibration damping unit 160 may prevent vibrations generated in the first bonding unit 120 from transmitting to the second bonding unit 130.

Specifically, when bonding of the second wire W2 is performed in the second bonding region R2 of the second bonding unit 130, the vibration damping unit 160 may prevent vibrations generated by the movement of the second bonding head 131 from transmitting to the first bonding unit 120. Further, when bonding of a first wire W1 is performed in the first bonding region R1 of the first bonding unit 120, the vibration damping unit 160 may prevent vibrations generated by the movement of the first bonding head 121 from transmitting to the second bonding unit 130.

Accordingly, the bonding apparatus according to an exemplary embodiment of the present inventive concept prevents vibrations transmitting between the first bonding unit 120 and the second bonding unit 130 driven independently of each other, thereby improving reliability of wire bonding.

The monitor 170 may be disposed on the second bonding unit 130. However, the arrangement position of the monitor 170 is not limited.

The monitor 170 may assist a user in setting the parameters of each of the first bonding unit 120 and the second bonding unit 130. Further, the user may monitor the wire bonding process performed in each of the first bonding unit 120 and the second bonding unit 130, using the monitor 170.

In the bonding apparatus according to an exemplary embodiment of the present inventive concept, the first bonding unit 120 and the second bonding unit 13,0 which are driven independently of each other, are disposed so as to be stacked in a direction perpendicular to a floor of a work place. Thus, it is possible to improve productivity and reduce the horizontal area occupied by the bonding apparatus.

Further, in the bonding apparatus according to an exemplary embodiment of the present inventive concept, by disposing the vibration damping unit 160 between the first bonding unit 120 and the second bonding unit 130 to prevent vibrations transmitting between the first bonding unit 120 and the second bonding unit 130 stacked in the vertical direction, it is possible to improve the reliability of wire bonding as well as increase the production capacity.

Hereinafter, a bonding apparatus according to another exemplary embodiment of the present inventive concept will be described with reference to FIG. 7. Differences from the bonding apparatus illustrated in FIG. 1 will be mainly described. Elements previously presented are as described above.

FIG. 7 is a diagram for explaining a vibration damping unit of a bonding apparatus according to another exemplary embodiment of the present inventive concept. Instead of the vibration damping unit 160 illustrated in FIG. 1, the bonding apparatus illustrated in FIG.1 may include, as a first vibration damping unit 161 or a first vibration damping unit 161, a vibration damping unit 260 as exemplarily shown in FIG. 7. Referring to FIG. 7, the vibration damping unit 260 includes a permanent magnet 261, an electromagnet 262 and a support unit 263.

Specifically, the permanent magnet 261 may be disposed on the lower surface of the second unloader 152, and the electromagnet 262 may be disposed on the upper surface of the first unloader 142. However, the present inventive concept is not limited thereto. That is, in other embodiments, the permanent magnet 261 may be disposed on the upper surface of the first unloader 142, and the electromagnet 262 may be disposed on the lower surface of the second unloader 152.

On an outer peripheral surface of the electromagnet 262, a coil enclosing the outer peripheral surface may be disposed. In this case, by supplying current along the coil, the polarity of the upper surface of the electromagnet 262 may be adjusted to be the same as the polarity of the permanent magnet 261.

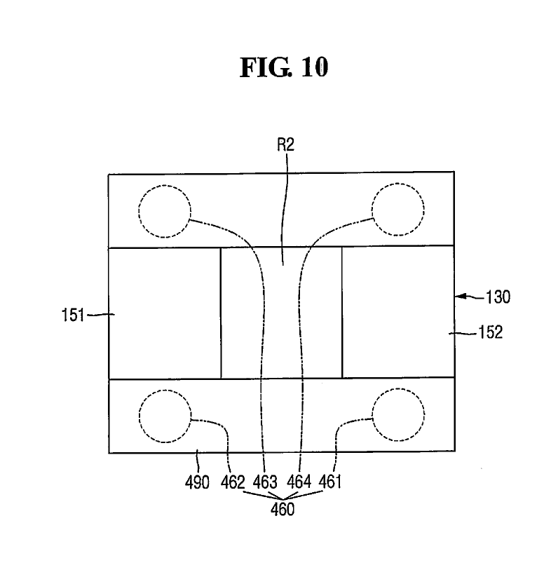

As a result, a repulsive force is generated between the electromagnet 262 and the permanent magnet 261, and it is possible to prevent vibrations transmitting between the first bonding unit (120 of FIG. 10) and the second bonding unit (130 of FIG. 1), using the repulsive force between the electromagnet 262 and the permanent magnet 261.

A spring with low rigidity, that is, relatively hard to be deformed, may be used as the support unit 263. The support unit 263 may support the second bonding unit (130 of FIG. 1), thereby preventing the electromagnet 262 and the permanent magnet 261 from coming into contact with each other.

However, the support unit 263 is not limited to the spring. That is, in other embodiments, other structures having elasticity may be used as the support unit 263.

Although FIG. 7 exemplary illustrates a configuration in which an individual vibration damping unit 260 is disposed between the first unloader 142 and the second unloader 152, it is a matter of course that a second vibration damping unit may also be disposed between the first loader (141 of FIG. 1) and the second loader (151 of FIG. 1). The second vibration damping unit may comprise the same elements as a first vibration damping unit, or may differ.

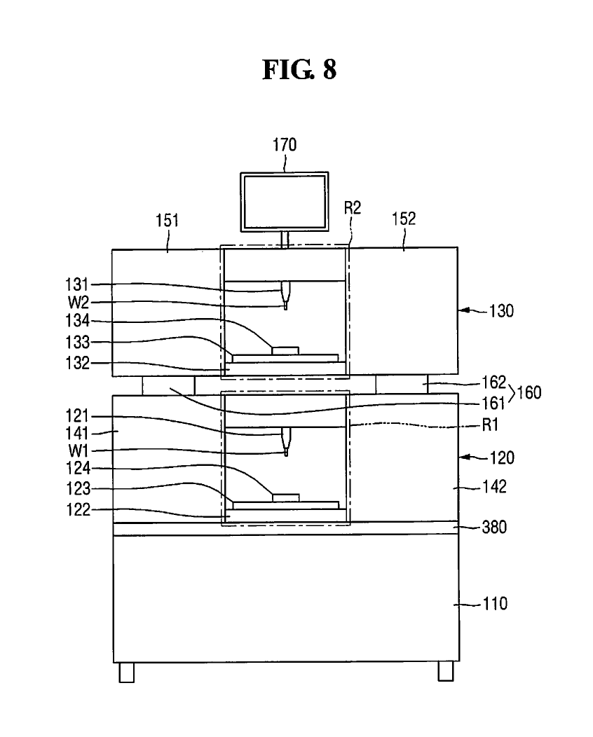

Hereinafter, a bonding apparatus according to an exemplary embodiment of the present inventive concept will be described with reference to FIG. 8. Differences from the bonding apparatus illustrated in FIG. 1 will be mainly described. Elements previously presented are as described above.

FIG. 8 is a diagram for explaining a bonding apparatus according to an exemplary embodiment of the present inventive concept.

Referring to FIG. 8, the bonding apparatus illustrated in FIG. 8 may further include a buffer unit 380 disposed between the console 110 and the first bonding unit 120, unlike the bonding apparatus illustrated in FIG. 1.

Specifically, the buffer unit 380 may perform a buffering function. For example, the buffer unit 380 may include rubber. However, the present inventive concept is not limited thereto. That is, in other embodiments, the buffer unit 380 may include other structures or substances capable of performing the buffering function.

The buffer unit 380 may prevent vibrations generated in the first bonding unit 120 from transmitting to the console 110. Further, the buffer unit 380 may prevent vibrations generated in the console 110 from transmitting to the first bonding unit 120.

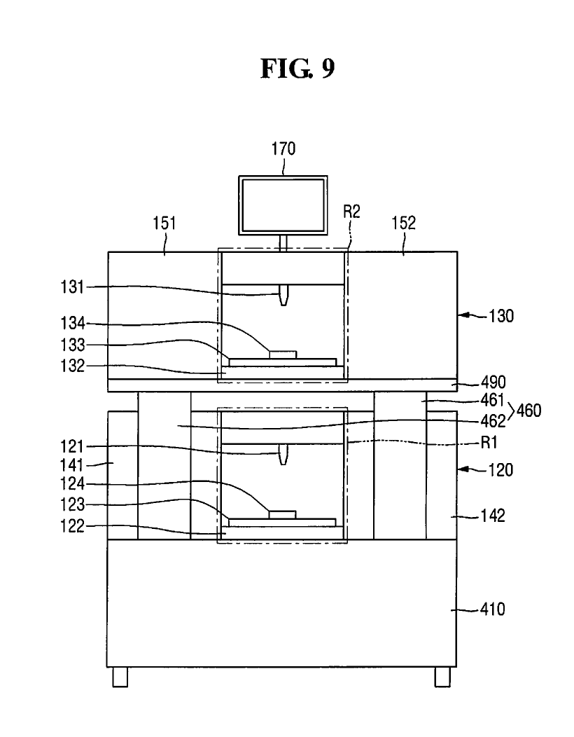

Hereinafter, the bonding apparatus according to an exemplary embodiment of the present inventive concept will be described with reference to FIG. 9 and FIG. 10.

Differences from the bonding apparatus illustrated in FIG. 1 and FIG. 2 will be mainly described. Elements previously presented are as described above.

FIG. 9 is a diagram for explaining a bonding apparatus according to an exemplary embodiment of the present inventive concept. FIG. 10 is a plan view of the bonding apparatus illustrated in FIG. 9. In FIG. 10, the monitor 170 is not illustrated for convenience of explanation.

Unlike the bonding apparatus illustrated in FIG. 1 and FIG. 2, referring to FIG. 9 and FIG. 10, the bonding apparatus illustrated in FIG. 9 and FIG. 10 may include a support plate 490 disposed below the second bonding unit 130, and a vibration damping unit 460 which connects the support plate 490 and the console 410.

Specifically, unlike the bonding apparatus illustrated in FIG. 1 and FIG. 2, in the bonding apparatus illustrated in FIG. 9 and FIG. 10, the vibration damping unit 460 is not connected to the first bonding unit 120, and connects the support plate 490 and the console 410. Also, the second bonding unit 130 may be disposed on the first bonding unit 120 to be spaced apart from the first bonding unit 120.

Furthermore, the vibration damping unit 460 may comprise 4 individual vibration damping units: a first vibration damping unit 461, a second vibration damping unit 462, a third vibration damping unit 463, and a fourth vibration damping unit 464. Each of the first vibration damping unit 461, second vibration damping unit 462, third vibration damping unit 463, and fourth vibration damping unit 464 contacts the support plate 490. The first and second vibration damping units 461 and 462 are paired on the front side of the second loader 151 and the second unloader 152. While the third and fourth vibration damping units 463 and 464 are paired on the back side the second loader 151 and the second unloader 152. The first and fourth vibration damping units 461 and 464 are on the side of second unloader 152, while the second and fourth vibration damping units 462 and 463 are on the side of second loader 151.

As a result, it is possible to prevent vibrations transmitting between the first bonding unit 120 and the second bonding unit 130. Furthermore, the first to fourth vibration damping units may comprise essentially similar units as presented in FIG. 7 above. Further still, a buffer as presented in FIG. 9 may be combined with a support plate.

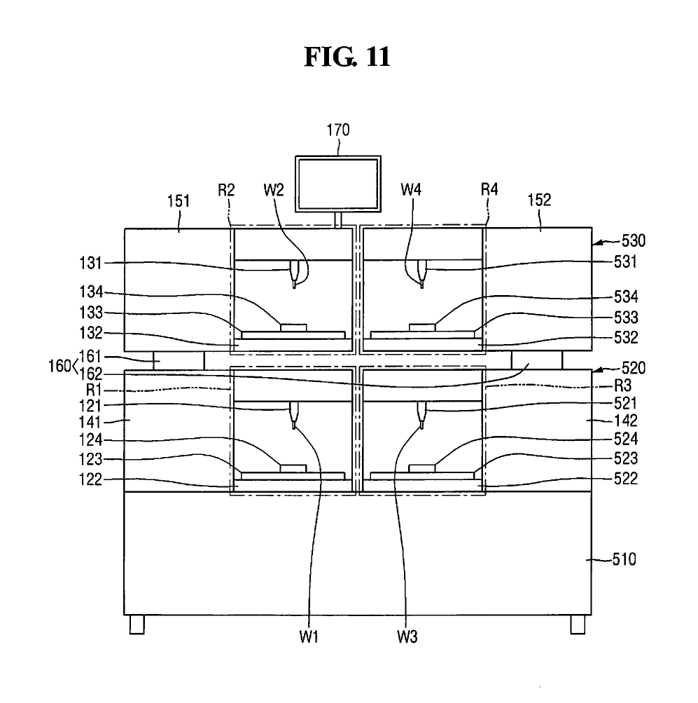

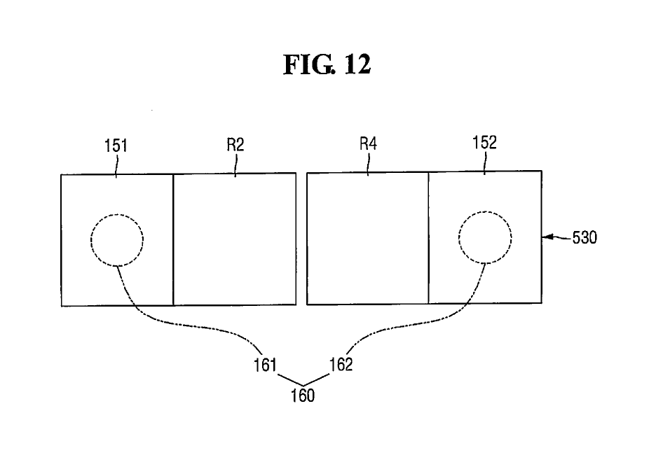

Hereinafter, a bonding apparatus according to still another exemplary embodiment of the present inventive concept will be described with reference to FIG. 11 and FIG. 12. Differences from the bonding apparatus illustrated in FIG. 1 and FIG. 2 will be mainly described. Elements previously presented are as described above.

FIG. 11 is a diagram for explaining a bonding apparatus according to still another exemplary embodiment of the present inventive concept. FIG. 12 is a plan view of the bonding apparatus illustrated in FIG. 11. In FIG. 12, the monitor 170 is not illustrated for convenience of explanation.

Unlike the bonding apparatus illustrated in FIG. 1 and FIG. 2, referring to FIG. 11 and FIG. 12, in the bonding apparatus illustrated in FIG. 11 and FIG. 12, the first bonding unit 520 may include a first bonding region R1 and a third bonding region R3, and the second bonding unit 530 may include a second bonding region R2 and a fourth bonding region R4.

Specifically, the first bonding unit 520 may include a first bonding region R1, and a third bonding region R3 spaced apart from the first bonding region R1 in the first direction. In this case, the first bonding region R1 and the third bonding region R3 may be disposed between the first loader 141 and the first unloader 142.

The first bonding unit 520 includes a first bonding region R1 comprising a first stage 122 on which the first substrate 123 is disposed, a first bonding head 121 disposed over the first stage 122, a first loader 141 disposed on one side of the first bonding region R1. The first bonding unit 520 also includes a third bonding region R3 comprising a third stage 522 on which the third substrate 523, different from the first substrate 123, is disposed, a third bonding head 521 disposed over the third stage 522, and a first unloader 142 disposed on the opposite side from R1 of the third bonding region R3.

By disposing the first bonding region R1 and the third bonding region R3 spaced apart from each other in the first direction, it is possible to prevent vibrations transmitting between the first bonding region R1 and the third bonding region R3.

The first substrate 123 may be loaded to the top of the first stage 122 of the first bonding region R1 via the first loader 141. Further, a third substrate 523 different from the first substrate 123 may also be loaded to the top of the third stage 522 of the third bonding region R3 via the first loader 141.That is, it is possible to provide substrates, which require wire bonding, to each of the first bonding region R1 and the third bonding region R3, using a single first loader 141. Also, it is possible to unload the completed substrates from each of the first bonding region R1 and the third bonding region R3, using a single first unloader 142.

In this case, the console 510 may individually drive both the first bonding head 121 installed in the first bonding region R1 and the third bonding head 521 installed in the third bonding region R3. Thus, a first wire W1 may be bonded to the first substrate 123 and the first semiconductor chip 124, and a third wire W3 may be bonded to the third substrate 523 and the third semiconductor chip 524 at the same time.

The second bonding unit 530 may include a second bonding region R2, and a fourth bonding region R4 spaced apart from the second bonding region R2 in the first direction. In this case, the second bonding region R2 and the fourth bonding region R4 may be disposed between the second loader 151 and the second unloader 152.

The second bonding unit 530 includes a second bonding region R2 comprising a second stage 132 on which the second substrate 133, different from the first substrate 123 and third substrate 523, is disposed, as well as a second bonding head 131 disposed over the second stage 132, and a second loader 151 disposed on one side of the second bonding region R2. The second bonding unit 530 also includes a fourth bonding region R4 comprising a fourth stage 532 on which a fourth substrate 533, different from the first substrate 123, second substrate 133 and third substrate 523, is disposed, as well as a fourth bonding head 531 disposed over the fourth stage 532 and a second unloader 152 disposed on the opposite side from R2 of the fourth bonding region R4.

By disposing the second bonding region R2 and the fourth bonding region R4 spaced apart from each other in the first direction, it is possible to prevent vibrations from transmitting between the second bonding region R2 and the fourth bonding region R4.

The second substrate 133 may be loaded to the top of the second stage 132 of the second bonding region R2 via the second loader 151. Further, a fourth substrate 533 different from the second substrate 133 may be loaded to the top of the fourth stage 532 of the fourth bonding region R4 via the second loader 151.That is, it is possible to provide substrates, which require wire bonding, to each of the second bonding region R2 and the fourth bonding region R4, using a single second loader 151. Also, it is possible to unload the completed substrates from each of the second bonding region R2 and the fourth bonding region R4, using a single second unloader 152.

In this case, the console 510 may individually drive both the second bonding head 131 installed in the second bonding region R2 and the fourth bonding head 531 installed in the fourth bonding region R4. As a result, a second wire W2 may be bonded to the second substrate 133 and the second semiconductor chip 134, and a fourth wire W4 may be bonded to the fourth substrate 533 and the fourth semiconductor chip 534 at the same time.

The third substrate 523, fourth substrate 533, third semiconductor chip 524, and fourth semiconductor chip 534 may be similar to the first substrate 123 and first semiconductor chip 124 as described above. The first wire W1, second wire W2, third wire W3, and fourth wire W4 may all be identical, or one or more wires may differ in one or more of size, shape, or composition.

Consequentially, in the bonding apparatus illustrated in FIG. 11 and FIG. 12, it is possible to improve productivity as compared to the horizontal area occupied by the bonding apparatus by simultaneously bonding wires to four substrates, using a single bonding apparatus.

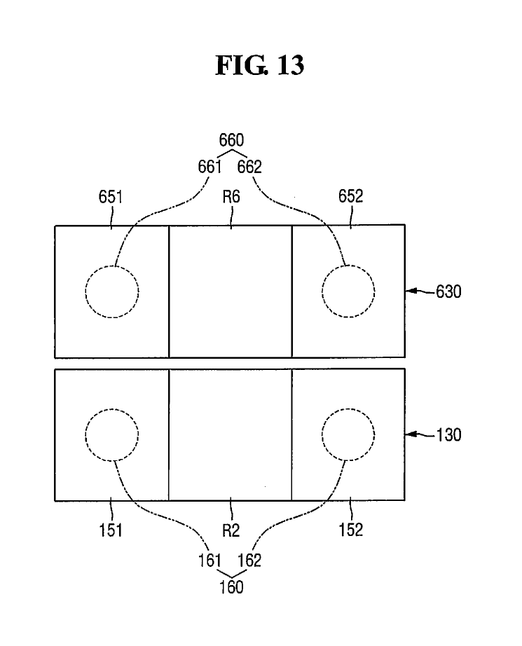

Hereinafter, a bonding apparatus according to still another exemplary embodiment of the present inventive concept will be described with reference to FIG. 13. Differences from the bonding apparatus illustrated in FIG. 1 and FIG. 2 will be mainly described. Elements previously described are as described above.

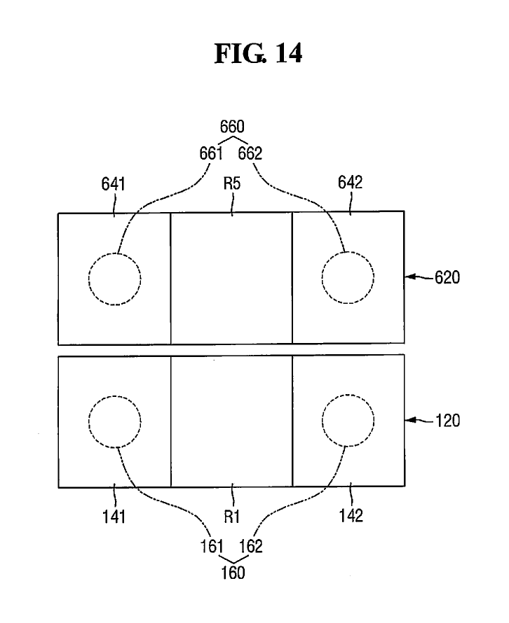

FIG. 13 is a plan view for explaining a bonding apparatus according to an exemplary embodiment of the present inventive concept. In FIG. 13, a monitor 170 is not illustrated for the sake of convenience of explanation. FIG. 14 is a plan view of the bonding apparatus of FIG. 13, taken from a different angle on the bonding apparatus.

Unlike the bonding apparatus illustrated in FIG. 1 and FIG. 2, referring to FIG. 1, 2 and FIG. 13, the bonding apparatus illustrated in FIG. 13 and FIG. 14 may further include a third bonding unit 620 spaced apart from the first bonding unit 120 in a second direction perpendicular to the first direction, and a fourth bonding unit 630 spaced apart from the second bonding unit 130 in the second direction. The fourth bonding unit 630 is on top of the third bonding unit 620, similar to manner in which the second bonding unit 130 is on top of the first bonding unit 120.

By disposing the first bonding unit 120 and the third bonding unit 620 to be spaced apart from each other in the second direction, it is possible to prevent vibrations from transmitting between the first bonding region R1 and the third bonding region.

Further, since the second bonding unit 130 and the fourth bonding unit 630 are disposed to be spaced apart from each other in the second direction, it is possible to prevent vibrations from transmitting between the second bonding region R2 and the fourth bonding region R6 Similarly to the first bonding unit 120, the third bonding unit 620 may be disposed on the console (not shown) and may be controlled by the console. The third bonding unit 620 may include a third stage on which the third substrate is disposed, a third bonding head disposed on the third stage to bond a third wire W3 to the third substrate, a third loader 641 disposed on one side of the third bonding region R5 of the third bonding unit 620 to load the third substrate to the third bonding region, and a third unloader 642 disposed on the other side of the third bonding region R5 of the third bonding unit 620 to unload the third substrate from the third bonding region R5.

Also, similarly to the second bonding unit 130, the fourth bonding unit 630 may be disposed on the third bonding unit, and may be controlled by the console. The fourth bonding unit 630 may include a fourth stage on which the fourth substrate is disposed, a fourth bonding head disposed on the fourth stage to bond the wire W4 to the fourth substrate, a fourth unloader 652 disposed on the one side of the fourth bonding region R6 of the fourth bonding unit 630 to load the fourth substrate to the fourth bonding region R6, and a fourth unloader 652 disposed on the other side of the fourth bonding region R6 of the fourth bonding unit 630 to unload the fourth substrate from the fourth bonding region R6.

Further, similar to the first bonding unit 120 having a vibration damping unit 160 between the first bonding unit 120 and second bonding unit 130, the third bonding unit 620 may have a vibration damping unit 660 between the third bonding unit 620 and the fourth bonding unit 630. Vibration damping unit 660 may be similar to the vibration damping units presented above, and may comprise a pair of vibration damping units 661 and 662 on opposite sides of each of the third and fourth bonding regions R5 and R6. Additional features such as the buffer of FIG. 8 or the support plate of FIG. 9 and FIG. 10 may also be installed.

The console thus may drive the first to fourth bonding units independently of each other. As a result, the bonding apparatus illustrated in FIG. 13 and FIG. 14 may improve the productivity compared to the horizontal area occupied by the bonding apparatus, by simultaneously bonding four wires to four substrates, using a single bonding apparatus. Furthermore, by spacing the first and third bonding units apart, and by using vibration damping units between units stacked on top of each other, the quality of the wire bonding may increase.

Although the exemplary embodiments according to the present inventive concept have been described with reference to the accompanying drawings, the present inventive concept is not limited to the above-described exemplary embodiments, and can be manufactured in various different forms. Those skilled in the art to which the present inventive concept pertains will understand that the exemplary embodiments may be provided in other specific forms, without changing the technical idea and features of the present inventive concept. It is therefore to be understood that the above-described exemplary embodiments are illustrative in all aspects and not restrictive.

While the present inventive concept has been particularly illustrated and described with reference to exemplary embodiments thereof, it will be understood by those of ordinary skill in the art that various changes in form and detail may be made therein without departing from the spirit and scope of the present inventive concept as defined by the following claims. The exemplary embodiments should be considered in a descriptive sense only and not for purposes of limitation.

What is claimed is:

1. A bonding apparatus comprising:
a console configured to control bonding of at least one wire;
a first bonding unit disposed on the console and configured to bond a first wire to a first substrate;
a second bonding unit disposed on the first bonding unit and configured to bond a second wire to a second substrate different from the first substrate; and
a vibration damping unit connected to the second bonding unit and configured to prevent a vibration generated in the second bonding unit from transmitting to the first bonding unit.

2. The bonding apparatus of claim 1, wherein the first bonding unit comprises a first stage for supporting the first substrate, and a first bonding head disposed over the first stage, and
the second bonding unit comprises a second stage for supporting the second substrate, and a second bonding head disposed over the second stage.

3. The bonding apparatus of claim 1, wherein the first bonding unit further comprises a first loader configured to load the first substrate to the first bonding unit, and a first unloader configured to unload the first substrate from the first bonding unit, and
the second bonding unit comprises a second loader configured to load the second substrate to the second bonding unit, and a second unloader configured to unload the second substrate from the second bonding unit.

4. The bonding apparatus of claim 1, wherein the vibration damping unit contacts the first bonding unit and the second bonding unit.

5. The bonding apparatus of claim 1, wherein the vibration damping unit contacts the console and the second bonding unit.

6. The bonding apparatus of claim 5, further comprising:
a support plate disposed below the second bonding unit and connected to the console through the vibration damping unit.

7. The bonding apparatus of claim 1, wherein the vibration damping unit comprises at least one of a spring and a rubber pad.

8. The bonding apparatus of claim 1, wherein the vibration damping unit comprises an electromagnet.

9. The bonding apparatus of claim 1, further comprising:
a buffer unit disposed between the console and the first bonding unit, wherein the buffer unit is configured to prevent vibrations generated in the first bonding unit from transmitting to the console.

10. The bonding apparatus of claim 1, wherein the console is configured to independently control the first bonding unit and the second bonding unit.

11. A bonding apparatus comprising:
a first stage configured to support a first substrate;
a second stage, which is disposed over the first stage and which is configured to support a second substrate different from the first substrate;
a first loader configured to load the first substrate onto the first stage in a first direction;
a second loader configured to load the second substrate onto the second stage in the first direction;
a first unloader configured to unload the first substrate from the first stage in the first direction;
a second unloader configured to unload the second substrate from the second stage in the first direction;
a first bonding head disposed between the first stage and the second stage and which is configured to bond a first wire to the first substrate;
a second bonding head disposed over the second stage and which is configured to bond a second wire to the second substrate; and
a vibration damping unit configured to prevent vibration generated in the second bonding head transmitting to the first bonding head.

12. The bonding apparatus of claim 11, further comprising:
a third stage, which is spaced apart from the first stage in the first direction, and which is configured to support a third substrate, different from the first and second substrates;
a fourth stage, which is spaced apart from the second stage in the first direction, and which is configured to support a fourth substrate, different from the first to third substrates;
a third bonding head disposed between the third stage and the fourth stage and which is configured to bond a third wire to the third substrate; and
a fourth bonding head disposed over the fourth stage and which is configured to bond a fourth wire to the fourth substrate.

13. The bonding apparatus of claim 12, wherein the first loader is configured to load the first and third substrates to each of the first and third stages, and
the second loader is configured to load the second and fourth substrates to each of the second and fourth stages.

14. The bonding apparatus of claim 11, further comprising:
a third stage, which is spaced apart from the first stage in a second direction perpendicular to the first direction, and which is configured to support a third substrate different, from the first and second substrates;
a fourth stage, which is spaced apart from the second stage in the second direction, and which is configured to support a fourth substrate, different from the first to third substrates;
a third bonding head which is disposed between the third stage and the fourth stage and which is configured to bond a third wire to the third substrate; and
a fourth bonding head disposed on the fourth stage and which is configured to bond a fourth wire to the fourth substrate.

15. The bonding apparatus of claim 14, further comprising:
a third loader configured to load the third substrate to the third stage; and
a fourth loader configured to load the fourth substrate to the fourth stage.

16. A bonding apparatus comprising:
a console configured to control bonding of at least one wire;
a first bonding unit disposed on the console and configured to bond a first wire to a first substrate;
a second bonding unit disposed on the first bonding unit and configured to bond a second wire to a second substrate different from the first substrate; and
a third bonding unit disposed on the console and configured to bond a third wire to a third substrate different from the first and second substrates, wherein the third bonding unit is spaced apart from the first bonding unit in a direction perpendicular from the second bonding unit.

17. The bonding apparatus of claim 16, further comprising a fourth bonding unit, disposed on the third bonding unit and configured to bond a fourth wire to a fourth substrate different from the first substrate, second substrate, and third substrate.

18. The bonding apparatus of claim 17, further comprising: a first vibration damping unit connected to the second bonding unit and configured to prevent a vibration generated in the second bonding unit from transmitting to the first bonding unit; and a second vibration damping unit connected between the third bonding unit and the fourth bonding unit and configured to prevent a vibration generated in the fourth bonding unit from transmitting to the third bonding unit.

19. The bonding apparatus of claim 1, wherein each vibration damping unit comprises a pair of vibration damping units.

20. The bonding apparatus of claim 1, wherein the first wire and the second wire differ in size, shape, or composition.
